(19) United States
(12) Patent Application Publication
(10) Pub. No.: US 2011/0262273 A1
(43) Pub. Date: Oct. 27, 2011

(54) Airfoil and blade for a turbine, and method for directly determining the progress of erosion of a turbine blade airfoil

(76) Inventors: Thomas Behnisch, Dresden (DE); Anett Berndt, Erlangen (DE); Christoph Ebert, Dresden (DE); René Füssel, Dresden (DE); Professor Werner Hufenbach, Dresden (DE); Albert Langkamp, Dresden (DE); Markus Mantel, Friedersdorf (DE); Heinrich Zeinninger, Obermichelbach (DE)

(21) Appl. No.: 13/124,446

(22) PCT Filed: Oct. 15, 2009
(86) PCT No.: PCT/EP09/63475

§ 371 Date: Jul. 13, 2011

(30) Foreign Application Priority Data
Oct. 20, 2008 (DE) 10 2008 052 380.1

(51) Int. Cl. F01D 5/14; G06F 19/00; G01R 27/08

(52) U.S. Cl. 416/61; 324/700; 702/34

(57) ABSTRACT

An airfoil of a turbine blade is provided. At least one sensor element is integrated into the material of the turbine blade airfoil in order to directly determine the progress of erosion of the turbine blade airfoil. Various methods for directly determining the progress of erosion of an airfoil of a turbine blade are also provided

### CROSS REFERENCE TO RELATED APPLICATIONS

This application is the US National Stage of International Application No. PCT/EP2009/063475, filed Oct. 15, 2009 and claims the benefit thereof. The International Application claims the benefits of European Patent Office application No. 10 2008 052 380.1 DE filed Oct. 20, 2008. All of the applications are incorporated by reference herein in their entirety.

### FIELD OF INVENTION

The present invention relates to a turbine bucket blade of a turbine bucket for a turbine as well as to a turbine bucket, in particular a final-stage turbine bucket, for a turbine, comprising a plurality of turbine bucket blades. The invention further relates to a method of directly determining the progress of erosion of a turbine bucket blade.

### BACKGROUND OF INVENTION

The final stage of a condensing steam turbine is mostly the limiting component in the design of the turbine as regards the maximum cross-flow area and/or the maximum rotational speed because the centrifugal forces lead to high stresses. The use of turbine buckets and/or turbine bucket blades made of a composite material, such as a fiber composite, in particular a carbon fiber reinforced fiber composite or a plastics material, has an advantageous effect due to the markedly lower mass of turbine buckets and/or turbine bucket blades designed in this manner.

Drop impact erosive stress, which erodes even hardened steel, is however a problem here. Composite materials, such as fiber composites, are less resistant to impact than hardened steel. Furthermore, in attempting to achieve a higher product of flow-off area and rotational speed, the peripheral speed and hence the erosion load of a turbine bucket and/or of the turbine bucket blades increases. As steam turbines occasionally have very long maintenance intervals, the use of composite materials, such as fiber composites, in particular carbon fiber reinforced fiber composites or plastics materials, is risky and may lead to failure of the steam turbine.

The turbine buckets and/or turbine bucket blades currently being used in steam turbines are still made, not of composite materials or fiber composites, but of steel or titanium.

A vibration-damping device and a method of actively damping vibrations of a component, in particular of a turbine bucket, are known from DE 102 55 009 A1. There, it is known that a piezo element is mounted on a turbine bucket and provided with a protective layer. Piezo elements may therefore be arranged on the intake side of a turbine bucket blade such that they are protected from erosion. The piezo element is connected to an electronic circuit that is configured to receive the current that is induced upon vibration of the turbine bucket by the deformation of the piezo element acting as a sensor, to process the current signal and to conduct a phase-offset current back to the piezo element. By means of such vibration damping counterforces may be applied to the component, for example the turbine bucket, in order to counteract a deformation of the component by the induced vibrations that arise.

The drawback of such vibration damping is that it does not allow any conclusions to be drawn about the state of erosion of the component. The mounting of the piezo elements on the turbine bucket has the drawback that these are rapidly damaged during operation of a turbine by drop impact stress and are therefore unable to provide measurement results over the long term.

### SUMMARY OF INVENTION

The object of the invention is to determine the component state, in particular the erosion state, of turbine buckets and/or turbine bucket blades continuously and reliably during operation of a turbine and hence allow conclusions to be drawn about the stability of the turbine buckets and/or turbine bucket blades.

This object is achieved according to the invention by a turbine bucket blade of a turbine bucket having the features as claimed in the claims, by a turbine bucket having the features as claimed in the claims, and by methods of directly determining the progress of erosion of a turbine bucket blade of a turbine bucket having the features as claimed in the claims. Further features and details of the invention emerge from the sub-claims, the description and the drawings. In this case, features and details that are described in connection with the turbine bucket blade according to the invention of a turbine bucket naturally apply also in connection with the turbine bucket according to the invention and/or the methods according to the invention of directly determining the progress of erosion of a turbine bucket blade of a turbine bucket, and vice versa in each case, so that with regard to the disclosure of the individual aspects of the invention reference is always made reciprocally.

According to the first aspect of the invention, the object is achieved by a turbine bucket blade of a turbine bucket for a turbine, in which at least one sensor element is integrated into the turbine bucket blade material of the turbine bucket blade for directly determining the progress of erosion of the turbine bucket blade.

The crux of the invention is that a sensor element is provided, by means of which the progress of erosion of a turbine bucket blade may be determined, namely continuously during the operation of the turbine bucket in a turbine. For this purpose, the sensor element is integrated directly into the turbine bucket blade material of the turbine bucket blade. In other words, the sensor element is implemented during the manufacturing process directly into the material of the turbine bucket blade so as to be surrounded on all sides by the material. Preferably, in this case the sensor element is integrated into the turbine bucket blade close to the region of the turbine bucket blade that is subject to drop impact stress and/or erosive stress. On the basis of the measured values measured by the sensor element conclusions may be drawn directly about the state of erosion of the turbine bucket blade. Naturally, during the manufacture of a turbine bucket blade it is also possible to integrate a plurality of sensor elements into the turbine bucket blade material of the turbine bucket blade. The sensor element may therefore be placed for example prior to introduction of the material in the casting mould so that, after the material is poured in, the sensor element is completely surrounded by this material.

The sensor element may comprise an accumulator for supplying power. The at least one sensor element is in this case connected by a cable connection or wirelessly to a display unit for displaying the measured values of the sensor element. Preferably the sensor element is a component part of a device for directly determining the progress of erosion of the turbine bucket blade. The device advantageously comprises a power supply unit, a display unit, an electronic circuit, a memory unit, a computing unit, a comparison device and/or a readout device. In this case, the at least one sensor element may be connected by a cable connection or in a cable-free manner to the device for directly determining the progress of erosion of the turbine bucket blade.

Such a turbine bucket blade enables direct determination of the progress of erosion at a turbine bucket blade of a turbine bucket, namely continuously during operation of the turbine bucket. Direct determination in the context of the invention means that the progress of erosion may be determined without conversion of the measured values and/or by simply relating the measured values to reference measured values. On the basis of a reference measured value in the normal state of the turbine bucket blade, the measured values measured by the sensor element during operation of the turbine bucket blade allow a conclusion to be drawn directly about the progress of erosion at the turbine bucket blade. With increasing erosion of the region of the turbine bucket blade that is subject to drop impact stress, the measured values change. This allows a direct conclusion to be drawn about the progress of erosion of the turbine bucket blade. For example, the measured sensor values may be compared with comparison values and/or reference measured values. It may therefore be easily and reliably determined when for example a critical limit value of the erosion wear has been reached.

The device and/or parts of the device for directly determining the progress of erosion of the turbine bucket blade may likewise be integrated into the turbine bucket material of the turbine bucket. These are implemented in the turbine bucket blade preferably at regions thereof that are not subject to erosive stress. In an advantageous manner these parts may alternatively be integrated into the platform of a turbine bucket.

The at least one sensor element may be configured in various ways and different measured variables may accordingly be acquired. The sensor element may for example take the form of an electric conductor and/or comprise an electric conductor.

A first constructional variant of the turbine bucket blade provides that the sensor element is configured to determine the electrical resistance of the integrated sensor element and/or of a conductor of the integrated sensor element. A variation of the turbine bucket blade, i.e. a deformation, for example a compression, an elongation or an erosion of a region of the turbine bucket blade, leads to a change of the sensor element and/or of the conductor of the sensor element and hence to a change of the electrical resistance of such a sensor element. On the basis of an electrical resistance reference value in the normal state of the turbine bucket blade, conclusions may be drawn about the progress of erosion at the regions of the turbine bucket blade that are subject to drop impact stress. As a sensor element, for example a strain gauge may be used. Strain gauges even in the event of slight deformation change their electrical resistance. The sensor element may also comprise other conductive wires, such as copper wires, the electrical resistance of which changes in the event of slight deformation. For measuring the electrical resistance of such a sensor element, the device for directly determining the progress of erosion of the turbine bucket blade preferably has a bridge circuit as an electric circuit. The determined electrical resistances may be compared with the reference resistance value in the normal state of the turbine bucket blade. The result of the comparison supplies direct conclusions about the state of erosion of the turbine bucket blade. If the region of the turbine bucket blade that is subject to erosive stress is eroded down to the sensor element, water drops impinge directly upon the sensor element. As a result of the impinging water drops the sensor element, in particular a strain gauge or a conducting wire, is short-circuited, with the result that the resistance suddenly changes significantly. Thus, the extent of erosion at this time may be precisely determined because the distance from the sensor element is known.

In a second preferred form of embodiment of the turbine bucket blade there is provision for the sensor element to be configured to emit and receive sound waves in order to determine the distance of the sensor element from the surface of the turbine bucket blade. The sensor element repeatedly emits sound waves in the direction of the region of the turbine bucket blade that is subject to erosive stress. The sound waves are reflected at the surface, i.e. the exterior, of the turbine bucket blade and sent back to the sensor element. On the basis of the propagation time of the sound wave from the time of emission to the time of reception by the sensor element a conclusion may be drawn directly about the distance traveled by the sound wave. This in turn provides information about the size of the volume of the turbine bucket blade that has been eroded by the drop impact erosive stress. In the normal state of the turbine bucket blade the distance between the sensor element and the exterior of the turbine bucket blade is known. Furthermore, as a result of the emitting of a sound wave by the sensor element, the time taken by the sound wave to arrive back at the sensor element may be acquired. On the basis of these reference values for the distance and the time taken by the sound wave to travel this double distance, conclusions may be drawn about the progress of erosion if during operation of the turbine the time interval between the emitting and the receiving of a sound wave by the sensor element decreases. The decreasing time is a direct parameter of the diminishing distance between the sensor element and the exterior of the turbine bucket blade. If part of the exterior of the turbine bucket blade has been eroded by drop impact stress, then the length of the distance remaining between the sensor element and the exterior of the turbine bucket blade may be determined by means of the determined time interval of the sound wave. An actual distance between the exterior of the turbine bucket blade and the sensor element may be determined by means of the equation: actual distance=reference distance in the normal state divided by the time of the sound wave in the normal state and multiplied by the actually measured time for the sound wave. Such a sensor element very rapidly and easily allows conclusions to be drawn about the remaining thickness of a turbine bucket blade. The sensor element merely has to be capable of emitting and receiving sound waves and measuring the time interval between the emitting and the receiving of a sound wave.

A turbine bucket blade is alternatively preferred, in which the sensor element is configured to determine the amplitude of a shock wave induced by a drop impact. In this third constructional variant of the turbine bucket blade the sensor element is configured in such a way that it may determine the amplitude of a shock wave triggered by a drop impact. The amplitude of a shock wave is a measure of the distance of the sensor element from the exterior of the turbine bucket blade. The greater the distance between the sensor element and the exterior of the turbine bucket blade, the lower the amplitude of the shock wave induced by a drop impact at the sensor element. If some of the exterior of the turbine bucket blade is eroded as a result of the drop impact erosive stress, then the distance between the exterior of the turbine bucket blade and the sensor element is shorter. The shorter this distance is, the greater is the amplitude of an induced shock wave at the sensor element. In other words, the measured amplitude of a shock wave is a direct measure of the distance of the sensor element from the exterior of the turbine bucket blade subject to erosive stress. Here too, an amplitude measured during operation of a turbine may be compared with a reference amplitude value determined in the normal state of the turbine bucket blade.

A fourth preferred constructional variant of a turbine bucket blade provides that the sensor element is configured to determine the force resulting from the centrifugal load and the direction of said force. The integrated sensor element determines the centrifugal force and the direction of said force, which acts upon the turbine bucket blade and the sensor element during rotation of the turbine bucket blade. The centrifugal force represents an inertial force that, owing to the inertia and the mass of the turbine bucket blade and the sensor element, acts upon the turbine bucket blade and the sensor element during a movement thereof. The centrifugal force may be measured from the mass of the moving turbine bucket blade and the sensor element, the velocity of the moving turbine bucket blade and the sensor element, and the radius of the circular path, along which the sensor element moves. If parts or a region of the turbine bucket blade are eroded as a result of drop impact erosive stress and if the variation of the distribution of the mass of the turbine bucket blade leads to a distortion of the turbine bucket blade and of the sensor element integrated into the turbine bucket blade material, then the strength and the direction of the centrifugal force acting upon the sensor element also change. This varied centrifugal force is determined by the sensor element and is an indication of the extent of the erosion at the region of the turbine bucket blade that is subject to drop impact stress. In particular, the variation of the mass of the turbine bucket blade leads to a change of the centrifugal load acting upon the sensor element. By comparing the actually acquired centrifugal force and the direction thereof with initial reference values, it is easily possible to make a precise statement about the state of the turbine bucket blade at the region subject to drop impact stress. First, the sensor element determines the centrifugal load acting upon the sensor element when the turbine bucket blade is in its normal state. The erosion caused by drop impact erosive stress leads to bucket distortion and hence to distortion of the sensor element. This results in a change in the strength and the angle of the resultant of the centrifugal load. Because of the angle change and the measured force of the resultant force compared to the reference values in the normal state of the turbine bucket blade, a conclusion may be drawn about the deformation and/or the shape of the turbine bucket blade.

A fifth preferred constructional variant of the turbine bucket blade provides that the sensor element comprises an actuator and a sensor for determining the amplitudes and the frequencies of local vibration modes and/or emitted sound waves between the actuator and the sensor. Actuator and sensor of the sensor element are integrated, mutually spaced apart, into the turbine bucket blade material, close to the region of the turbine bucket blade that is subject to drop impact stress. The sensor measures the amplitude and the frequency of a wave emitted by the actuator. Thus, as a reference amplitude and frequency value, the amplitude and the frequency a wave when the turbine bucket blade is in the normal state may be determined. If the mass and the shape of the turbine bucket blade changes after drop impact stressing, then the amplitude and frequency of a wave emitted by the actuator also varies. The actuator may emit for example acoustic or electromagnetic waves. If as a result of erosion the exterior of the turbine bucket blade is disposed closer to the sensor element, i.e. the actuator and the sensor, then the local vibration mode of the emitted wave changes. This variation is an indication of the variation of the turbine bucket blade. For example, with decreasing thickness of the turbine bucket blade, the amplitude and the frequency of the emitted wave decrease.

A sixth preferred constructional variant of the turbine bucket blade provides that the sensor element is configured to determine the natural vibration frequencies of the turbine bucket blade. A turbine bucket blade at a special rotational speed of the turbine buckets is excited into a specific natural vibration and/or into specific natural vibration modes. The frequency of the natural vibration varies as a result of progressive erosion. By means of repeated measurement of the natural vibration frequency of the turbine bucket blade and comparison of the measured natural vibration frequencies with natural vibration frequency that were determined in the normal state of the turbine bucket blade, conclusions may be drawn about the progress of erosion at the turbine bucket blade. The reduced mass of a turbine bucket blade as a result of erosion alters the position of the center of gravity of the turbine bucket blade. This leads to varied vibration modes of the turbine bucket blade and to a shift of the natural frequencies, which may be detected by the sensor element. No actuator is necessary for determining the natural vibration frequencies.

The sensor element is integrated during the manufacture of the turbine bucket blade directly into the turbine bucket blade material. This may be realized for example by means of a casting method. In this case, the sensor element is placed in the casting mold and completely surrounded by the introduced turbine bucket blade material, for example a plastics material. A turbine bucket blade is moreover preferred in which the turbine bucket blade material takes the form of a composite material, in particular a fiber composite. A composite material is a material comprising a combination of two or more materials. Through the use of two or more materials composite materials may possess a very high strength. At the same time, the weight of a turbine bucket blade made of a composite material may be kept low compared to a turbine bucket blade made of steel.

The turbine bucket blade material may for example take the form of a carbon fiber reinforced plastics material (CRP). In such a material, carbon fibers are embedded as reinforcement in the plastics material. The turbine bucket blade material may further take the form of a ceramic fiber composite. A fiber composite consists of reinforcing fibers and a plastics material matrix that surrounds the fibers. The fibers are bonded by adhesive or cohesive forces to the plastics material matrix. Through the use of fibers, fiber composites have a direction-independent resilience. Such fiber composites are extremely rigid and strong and are therefore suitable for use as a turbine bucket blade. By means of the at least one integrated sensor element the stability and/or the progress of erosion of a turbine bucket blade configured in such a manner may be determined easily and reliably during operation in a turbine. A further possibility provides that the turbine bucket blade material comprises wood, a paste or similar materials.

A further preferred construction of the turbine bucket blade provides that the sensor element comprises at least one piezo sensor, at least one strain gauge or at least one conductive wire, in particular a copper wire.

A piezo sensor or a piezoelectric sensor is a general-purpose sensor element that is capable of acquiring measured variables such as a voltage, a pressure, a force or an acceleration. Strain gauges even in the event of slight deformation alter their electrical resistance. If a drop impact leads to deformation of the turbine bucket blade, the strain gauge also deforms and the electrical resistance varies. The varied electrical resistance value is therefore a measure of the deformation of the turbine bucket blade. Other conductive wires, in particular copper wires, may be used as part of the sensor element. The sensor element allows early detection of damage at a turbine bucket blade.

The sensor element and/or the strain gauge or the conductive wire of the sensor element is advantageously of a serpentine configuration. This allows the sensor element to be disposed over a larger region in the turbine bucket blade material. The serpentine strain gauge and/or the serpentine wire is preferably disposed in the turbine bucket blade material offset relative to the exterior of the region subject to drop impact stress. Naturally, depending on the development of the turbine bucket blade, other forms of the strain gauge and/or the conductive wire are also possible.

According to the second aspect of the invention the objects are achieved by a turbine bucket, in particular a final-stage steam turbine bucket, for a turbine, comprising a plurality of turbine bucket blades, wherein at least two of the turbine bucket blades are configured in accordance with a constructional variant of the first aspect of the invention and wherein a comparison device is provided for comparing the progress of erosion of the at least two turbine bucket blades. By virtue of the fact that at least two turbine bucket blades are configured with in each case at least one sensor element, by means of the comparison device a conclusion may be drawn about the deformation of all of the turbine bucket blades of the turbine bucket. Turbine bucket in the context of the invention is taken to mean an entire unit comprising a plurality of turbine bucket blades. If some of the turbine bucket blades are provided with sensor elements, by means of the measurement results of these sensor elements, conclusions may be drawn about the state of the turbine bucket blades that do not have sensor elements. By means of the comparison device it is possible for example to determine the average damage to all of the turbine bucket blades or to determine the turbine bucket blade where the damage is greatest. By virtue of mounting and/or integrating sensor elements into a plurality of turbine bucket blades, by means of the difference of the signals and/or of the measured values a conclusion may be drawn about the state of individual turbine bucket blades.

According to the third aspect of the invention the object is achieved by various methods of directly determining the progress of erosion of a turbine bucket blade of a turbine bucket.

A first method of directly determining the progress of erosion of a turbine bucket blade of a turbine bucket, the turbine bucket blade being configured in accordance with the first constructional variant of the turbine bucket blade of the first aspect of the invention, achieves the object in that the sensor element repeatedly measures its electrical resistance and/or the electrical resistance of a conductor of the integrated sensor element and that the electrical resistances of the repeated measurements are compared with one another to determine the progress of erosion of the turbine bucket blade. The measurements of the electrical resistance may be repeated at regular or irregular intervals. By means of a plurality of measurements the progress of erosion at the turbine bucket blade may be determined. A deformation of the turbine bucket blade as a result of a drop impact leads likewise to a deformation of the sensor element, with the result that the electrical resistance of the sensor element changes. The measured electrical resistances are compared with a reference resistance value that is determined when the turbine bucket blade is in its normal state. The result of the comparison of the measured electrical resistances with the reference resistance value supplies direct conclusions about the state of erosion of the turbine bucket blade.

A second method of directly determining the progress of erosion of a turbine bucket blade of a turbine bucket, the turbine bucket blade being configured in accordance with the second constructional variant of the turbine bucket blade of the first aspect of the invention, achieves the object in that the sensor element repeatedly emits sound waves and measures the time that each emitted sound wave, which is reflected at the surface of the turbine bucket blade, takes to be received again by the sensor element, that the distances of the sensor element from the surface of the turbine bucket blade are determined by multiplying each measured time by the known distance of the sensor element from the surface of the turbine bucket blade in an initial state of the turbine bucket blade and by dividing the measured time taken by the sound wave between being emitted and received in the initial state of the turbine bucket blade, and that on the basis of the calculated distances the progress of erosion of the turbine bucket blade is determined. First, the sensor element acquires the time that a sound wave emitted by it takes to arrive back at the sensor element. As the distance between the sensor element and the exterior of the turbine bucket blade in the normal state of the turbine bucket blade is known, a time for an emitted sound wave may also be determined for this distance. This distance serves as a reference distance, the determined time serves as a reference time. If during operation of the turbine a sound wave is transmitted to the exterior of the turbine bucket blade and the time taken by this sound wave to arrive back at the sensor element is determined, then on the basis of this determined time as well as the reference time and the reference distance, the distance traveled by the sound wave may be determined. Because of erosion at the exterior of the turbine bucket blade the time taken by the sound wave will be shorter than the reference time. The distance is accordingly also shorter than the reference distance. The actual distance of the sensor element from the surface of the turbine bucket blade is calculated by multiplying the determined time of an actually emitted sound wave by the reference distance and dividing the product of this multiplication by the reference time. Thus, in a very simple manner the, in each case, actual distance of the sensor element from the surface of the turbine bucket blade is determined. If the distance of the sensor element from the surface of the turbine bucket blade is known, it is also easy to determine how much of the turbine bucket blade has actually been abraded by erosive stress.

A third method of directly determining the progress of erosion of a turbine bucket blade, the turbine bucket blade being configured in accordance with the third constructional variant of the turbine bucket blade of the first aspect of the invention, achieves the object in that the sensor element repeatedly determines the amplitude of a shock wave induced by a drop impact and that on the basis of a comparison of the determined amplitudes the progress of erosion of the turbine bucket blade is determined. The amplitude of a shock wave is a measure of the distance of the sensor element from the exterior of the turbine bucket blade. As the distance of the sensor element from the exterior of the turbine bucket blade in the normal state of the turbine bucket blade is known, a reference amplitude value may also be determined for this distance. As a result of the erosion wear the distance of the exterior of the turbine bucket blade from the sensor element decreases, so that upon the occurrence of a further shock wave a varied amplitude is determined by the sensor element. Because of the decreasing distance, the measured amplitude value increases.

A fourth method of directly determining the progress of erosion of a turbine bucket blade of a turbine bucket, the turbine bucket blade being configured in accordance with the fourth constructional variant of the turbine bucket blade of the first aspect of the invention, achieves the object in that the sensor element repeatedly measures the centrifugal load acting upon the sensor element, and that on the basis of each measured centrifugal load the resultant force and the direction thereof is determined, and that by means of a comparison of the determined resultant forces and the directions thereof the progress of erosion of the turbine bucket blade is determined. In this case, the sensor element measures the mass of the moving turbine bucket blade and the velocity at which the sensor element is moving. The radius of the circular path along which the sensor element moves is moreover known to the sensor element. In the event of erosion of a region of the turbine bucket blade, the mass of the turbine bucket blade and/or the distribution of the mass of the turbine bucket blade varies. As a result of this, the strength and the direction of the centrifugal force acting upon the sensor element varies. This varied centrifugal force is a measure of the extent of the erosion at the region of the turbine bucket blade that is subject to drop impact stress. The erosion at the turbine bucket blade leads to bucket distortion and to a distortion of the sensor element. As a result, the strength and the angle of the resultant force of the centrifugal load change. The permanently determined centrifugal force and its direction are compared with initial reference values. In this way the extent of the erosion at the turbine bucket blade may be determined. On the basis of the angle change and the measured force of the resultant compared to the initial reference values in the normal state of the turbine bucket blade a conclusion may be drawn about the deformation and/or the shape of the turbine bucket blade.

A fifth method of directly determining the progress of erosion of a turbine bucket blade of a turbine bucket, the turbine bucket blade being configured in accordance with the fifth constructional variant of the turbine bucket blade of the first aspect of the invention, achieves the object in that the actuator of the sensor element repeatedly emits sound waves, and that the sensor of the sensor element determines the amplitudes of each sound wave and the time between the impingement of two successive sound waves, and that on the basis of a comparison of the repeatedly determined measurement data the progress of erosion of the turbine bucket blade is determined. By virtue of the fact that the actuator and the sensor of the sensor element are arranged mutually spaced apart, the sensor is able to detect a wave emitted by the actuator, in particular an acoustic wave. This wave has a specific vibration mode. If the exterior of the turbine bucket blade changes, this has an influence on the vibration mode of an emitted wave, in particular a sound wave. With decreasing thickness of the turbine bucket blade, for example the amplitude of the vibration of the wave varies to the effect that it has a progressively smaller value. The determined amplitude values and the determined frequency values of the local vibration modes are compared with the reference amplitude values and reference frequency values, so that information may be gained about the state of erosion of the turbine bucket blade.

A sixth method of directly determining the progress of erosion of a turbine bucket blade of a turbine bucket, the turbine bucket blade being configured in accordance with the sixth constructional variant of the turbine bucket blade of the first aspect of the invention, achieves the object in that the sensor element repeatedly measures the natural vibration frequencies of the turbine bucket blade, and that the progress of erosion of the turbine bucket blade is determined on the basis of a comparison of the determined natural vibration frequencies. The measurement of the natural vibration frequencies of the turbine bucket blade may be carried out for example by means of a piezo sensor or a strain gauge. By comparing the measured natural vibration frequencies with reference natural vibration frequencies the progress of erosion at the turbine bucket blade may be determined.

One of the previously described methods of directly determining the progress of erosion of a turbine bucket blade of a turbine bucket is moreover preferred in which the turbine bucket blade is configured in accordance with the first aspect of the invention.

A method of directly determining the progress of erosion of a turbine bucket blade of a turbine bucket is moreover preferred in which, by means of the comparison of the progress of erosion of at least two turbine bucket blades, conclusions are drawn about the progress of erosion of individual turbine bucket blades. It is therefore also possible to assess the state of a turbine bucket blade that has no sensor elements. Conclusions about the overall state of a turbine bucket are moreover possible.

### BRIEF DESCRIPTION OF THE DRAWINGS

There now follows a detailed description of embodiments of the invention with reference to the accompanying drawings. The drawings show:

FIG. 1 a perspective view of a turbine bucket blade with an integrated first sensor element;

FIG. 2 a cross-sectional view of the turbine bucket blade according to FIG. 1;

FIG. 3 a cross-sectional view of a turbine bucket blade with an integrated second sensor element;

FIG. 4 an enlarged representation of a detail of a turbine bucket blade according to FIG. 3;

FIG. 5 an enlarged representation of a detail of a turbine bucket blade according to FIG. 3;

FIG. 6 a cross-sectional view of a turbine bucket blade with an integrated third sensor element;

FIG. 7 a cross-sectional view of a turbine bucket blade with an integrated third sensor element;

FIG. 8 a perspective view of a turbine bucket blade with an integrated fourth sensor element;

FIG. 9 a perspective view of a turbine bucket blade with an integrated fourth sensor element;

FIG. 10 a cross-sectional view of a turbine bucket blade with an integrated fifth sensor element;

FIG. 11 an enlarged representation of a detail of a turbine bucket blade according to FIG. 10;

FIG. 12 an enlarged representation of a detail of a turbine bucket blade according to FIG. 10.

### DETAILED DESCRIPTION OF INVENTION

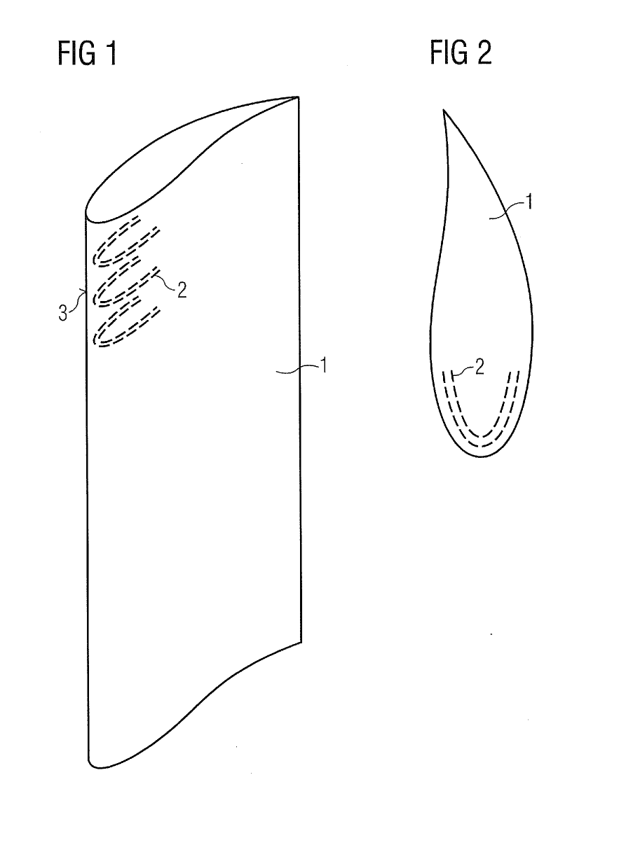

In FIG. 1 a perspective of a turbine bucket blade 1 is shown. A sensor element 2 is integrated into the turbine bucket blade 1. In other words, the sensor element 2 is integrated into the turbine bucket blade material. In this constructional variant of the turbine bucket blade 1 the sensor element 2 is configured to determine the electrical resistance of the integrated sensor element 2 and/or of a conductor of the integrated sensor element 2. The sensor element 2 comprises a strain gauge of a serpentine configuration and/or a conductive wire of a serpentine configuration. The sensor element 2 and/or the conductor of the sensor element 2 is, as represented in FIG. 2, disposed close to the surface/exterior 3 of the turbine bucket blade 1 that is subject to drop impact stress. The sensor element 2 may therefore continuously determined [sic] the progress of the erosion caused by the drop impact stress at the surface/exterior 3 of the turbine bucket blade 1. The sensor element 2 is connected by a cable or in a cable-free manner to a device (not shown) for directly determining the progress of erosion of the turbine bucket blade 1. The measured variables acquired by the sensor element 2 are communicated to the device and processed there.

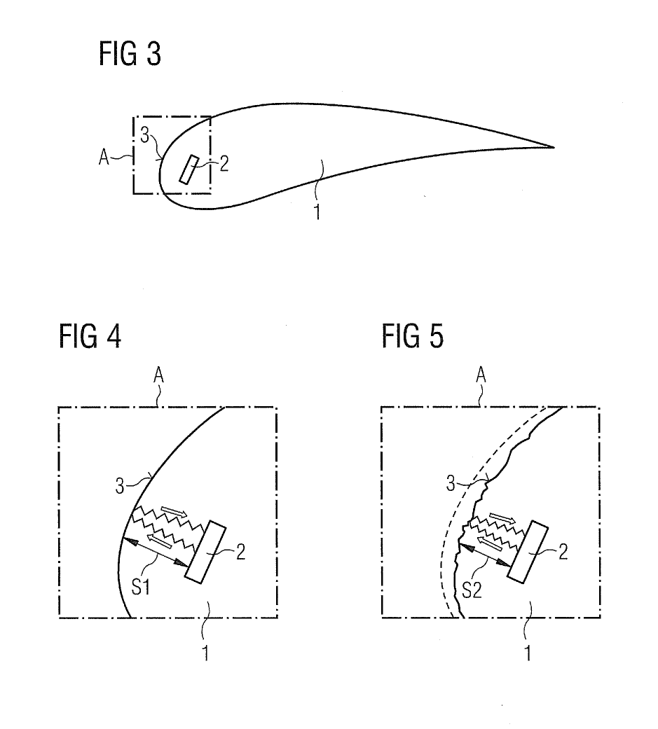

In FIGS. 3 to 5 a turbine bucket blade 1 having a different, second sensor element 2 is represented. In this constructional variant of the turbine bucket blade 1 the sensor element 2 is configured to emit and receive sound waves in order to determine the distance of the sensor element 2 from the surface 3 of the turbine bucket blade 1. The sensor element 2 emits a sound wave in the direction of the surface 3 of the turbine bucket blade 1. At the surface 3 the sound wave is reflected and sent back to the sensor element 2. The sensor element 2 measures the time between the emitting and the receiving of the sound wave. The shorter the measured time is, the shorter is the distance of the sensor element 2 from the surface 3 of the turbine bucket blade 1. In other words, by means of the measured time the progress of erosion at the surface/exterior 3 of the turbine bucket blade 1 may be directly determined. In FIG. 3 the position of the sensor element 2 within the turbine bucket blade 1 is represented. The sensor element 2 is disposed close to the region of the turbine bucket blade 1 that is subject to drop impact stress. FIGS. 4 and 5 show an enlarged representation of the detail A outlined by dashes in FIG. 2. In FIG. 4 the surface/exterior 3 of the turbine bucket blade 1 is undamaged. In this normal state of the turbine bucket blade 1 the sensor element 2 is disposed at a distance S1 from the surface/exterior 3 of the turbine bucket blade 1. The propagation time, which the emitted sound wave travels between its being emitted and received, is denoted by t1. In FIG. 5 the surface/exterior 3 of the turbine bucket blade 1 has been damaged and/or eroded by drop impact. The propagation time now traveled by the sound wave and measured by the sensor element 2 is denoted by S2. The distance S2 between the sensor element 2 and the erosion-damaged surface 3 of the turbine bucket blade 1 may be calculated using the formula

S2=S1×t2/t1

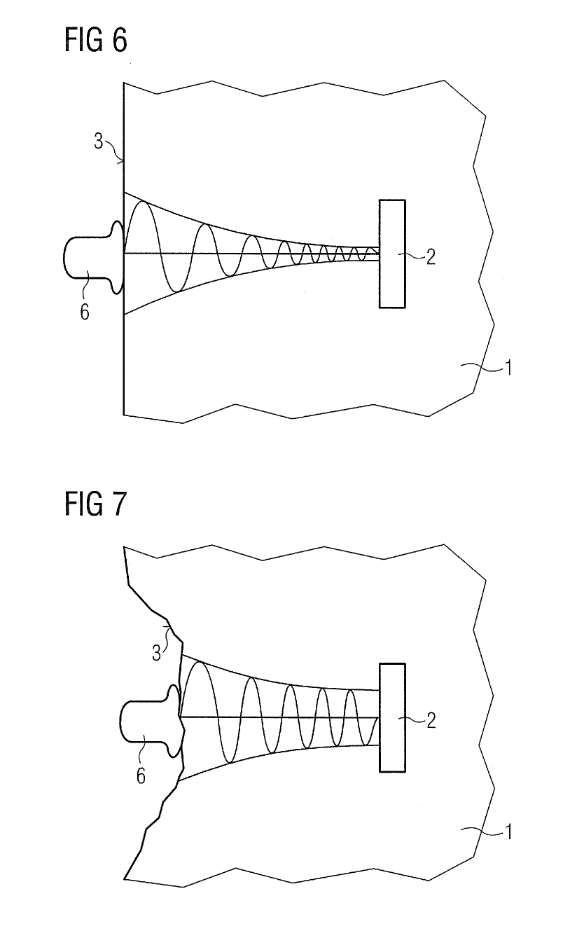

In FIGS. 6 and 7 a cross-sectional view of a turbine bucket blade 1 with an integrated third sensor element 2 is represented. From FIG. 6 it is evident that a drop 6 impinging on the surface/exterior 3 of the turbine bucket blade 1 triggers a shock wave, which is detected by the sensor element 2. The sensor element 2 is configured to determine the amplitude of the shock wave induced by the drop impact. The sensor element 2 may moreover determine the frequency of the shock wave. The greater the distance between the surface/exterior 3 of the turbine bucket blade 1, the lower the amplitude of the shock wave that is measured by the sensor element 2. In FIG. 7 a region of the surface/exterior 3 of the turbine bucket blade 1 has been eroded by the drop impact stress, with the result that the distance between the surface/exterior 3 and the sensor element 2 is smaller than is represented in FIG. 6. The shock wave induced by the drop 6 has, in the region of the sensor element 2 in FIG. 7, a greater amplitude value than that measured by the sensor element 2 in FIG. 6. The size of the amplitude value is therefore a direct measure of the progress of erosion at the turbine bucket blade 1.

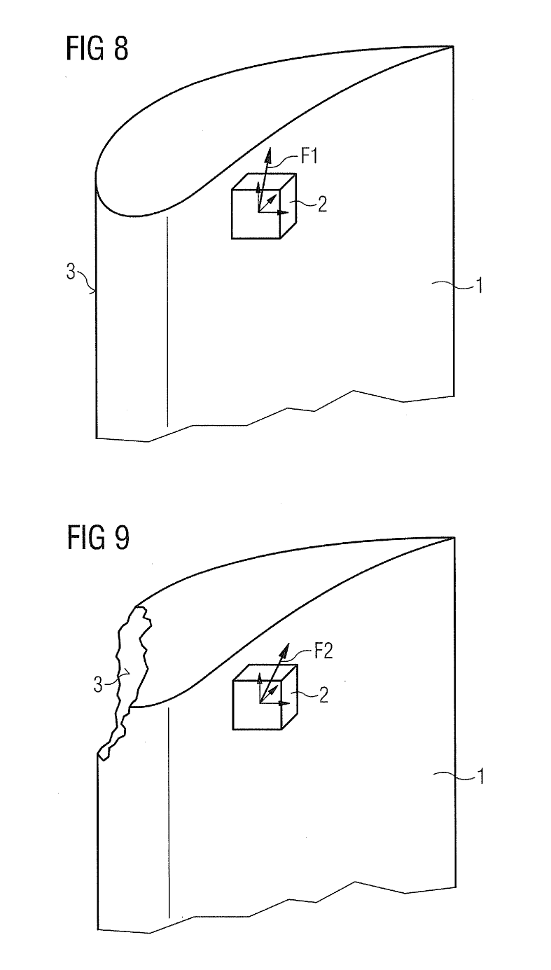

FIGS. 8 and 9 show in each case a perspective view of a turbine bucket blade 1 with an integrated fourth sensor element 2. The sensor element 2 is configured to determine the force resulting from the centrifugal load and the direction of this force. In an initial state of the turbine bucket blade 1 that is represented in FIG. 8, the sensor element 2 during a rotation of the turbine bucket blade 1 measures a resulting centrifugal load F1. This centrifugal load F1 is composed of the force acting upon the sensor element 2 as well as the direction of the force. If the surface/exterior 3 of the turbine bucket blade 1 is eroded as a result of drop impact stress, then as a result of the effective forces, the turbine bucket blade 1 and hence the sensor element 2 are deformed and/or distorted. The erosion moreover leads to a variation of the mass of the turbine bucket blade 1. This gives rise to a change both in the force and in the direction, in which the force acts upon the sensor element 2. The resulting centrifugal load F2, in the case of a turbine bucket blade 1 damaged by drop impact, is represented in FIG. 9. This centrifugal load F2 has a different angle and a different resultant force than the centrifugal load F1 according to FIG. 8.

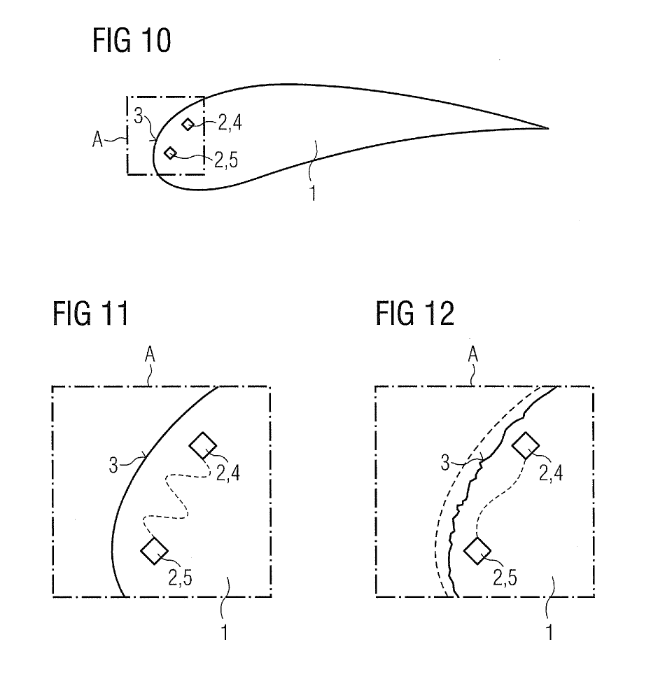

FIGS. 10 to 12 show a cross-sectional view of a turbine bucket blade 1 with an integrated fifth sensor element 2. In this constructional variant of the turbine bucket blade 1 the sensor element 2 comprises an actuator 4 and a sensor 5 for determining the amplitudes and the frequencies of local vibration modes and/or emitted sound waves between the actuator 4 and the sensor 5. The actuator 4 and the sensor 5 are disposed spaced apart, close to the region of the turbine bucket blade 1 that is subject to drop impact stress. In FIGS. 11 and 12 the detail A outlined by dashes is represented to an enlarged scale. In FIG. 11 the turbine bucket blade 1 is in a normal state. The sensor 5 receives a wave emitted by the actuator 4, in particular an acoustic wave such as a sound wave. This wave has a characteristic vibration mode, i.e. a characteristic amplitude and frequency. If the surface/exterior 3 of the turbine bucket blade 1 is eroded as a result of drop impact, the distance of the sensor element 2, i.e. of the actuator 4 and the sensor 5 thereof, from the surface/exterior 3 varies. As a result of the varied shape of the turbine bucket blade 1 a freshly emitted wave has a different characteristic vibration mode. For example, the amplitude and the frequency of such a wave decrease, see FIG. 12. This variation of the vibration mode is a direct measure of the progress of erosion at the turbine bucket blade 1.

The sensor elements 2 in this case are always disposed in the region of a turbine bucket blade 1 that is subject to erosive stress. The reduction of the mass of a turbine bucket blade 1 that is caused by erosion changes the position of the center of gravity of the turbine bucket blade 1 and of the sensor element 2. This leads to varied vibration modes and to a shift of the natural frequencies which are detected. By mounting the sensor elements 2 in a plurality of turbine bucket blades 1 it is possible on the basis of the difference of the signals and/or measured variables that are measured to draw a conclusion about the state of individual turbine bucket blades 1. The previously described methods and the special development of the turbine bucket blade 1 enable early detection of damage at a turbine bucket blade 1. The sensor elements 2 may be used for further analysis.

1.-20. (canceled)

21. A turbine bucket blade of a turbine bucket for a turbine, comprising:
a sensor element, integrated into a turbine bucket blade material of the turbine bucket blade for directly determining the progress of erosion of the turbine bucket blade.

22. A turbine bucket blade as claimed in claim 21, wherein the sensor element is a component part of a device for directly determining the progress of erosion of the turbine bucket blade.

23. A turbine bucket blade as claimed in claim 21, wherein the sensor element is configured to determine an electrical resistance of the integrated sensor element and/or of a conductor of the integrated sensor element.

24. A turbine bucket blade as claimed in claim 21, wherein the sensor element is configured to emit and receive sound waves in order to determine a distance of the sensor element from a surface of the turbine bucket blade.

25. A turbine bucket blade as claimed in claim 21, wherein the sensor element is configured to determine an amplitude of a shock wave induced by a drop impact.

26. A turbine bucket blade as claimed in claim 21, wherein the sensor element is configured to determine a force resulting from a centrifugal load as well as a direction of the force.

27. A turbine bucket blade as claimed in claim 21, wherein the sensor element comprises an actuator and a sensor for determining a plurality of amplitudes and a plurality of frequencies of local vibration modes and/or emitted sound waves between the actuator and the sensor.

28. A turbine bucket blade as claimed in claim 21, wherein the sensor element is configured to determine a plurality of natural vibration frequencies of the turbine bucket blade.

29. A turbine bucket blade as claimed in claim 21, wherein the turbine bucket blade material is a composite material.

30. A turbine bucket blade as claimed in claim 29, wherein the composite material is a fiber composite material.

31. A turbine bucket blade as claimed in claim 21,
wherein the sensor element comprises a piezo sensor, a strain gauge, or a conductive wire.

32. A turbine bucket blade as claimed in claim 31, wherein the sensor element comprises a copper wire.

33. A turbine bucket blade as claimed in claim 21, wherein the sensor element includes a serpentine configuration.

34. A method of directly determining the progress of erosion of a turbine bucket blade of a turbine bucket, comprising:
repeatly measuring an electrical resistance of a sensor element and/or the electrical resistance of a conductor of an integrated sensor element; and
comparing the electrical resistances of the repeated measurements with one another in order to determine the progress of erosion of the turbine bucket blade.

35. A method of directly determining the progress of erosion of a turbine bucket blade of a turbine bucket, comprising:
repeatedly emitting a plurality of sound waves by a sensor element;
measuring, by the sensor element, the time that each emitted sound wave, which is reflected at a surface of the turbine bucket blade, takes to be received again by the sensor element;
determining the distances of the sensor element from the surface of the turbine bucket blade by multiplying each measured time by a known distance of the sensor element from the surface of the turbine bucket blade in an initial state of the turbine bucket blade and by dividing the measured time taken by the sound wave between being emitted and received in the initial state of the turbine bucket blade; and
determining, on the basis of the calculated distances, the progress of erosion of the turbine bucket blade.
